(19) United States
(12) Patent Application Publication
(10) Pub. No.: US 2025/0320604 A1
(43) Pub. Date: Oct. 16, 2025

(54) LOW TEMPERATURE PLASMA DEPOSITION OF SILICON-CONTAINING FILMS USING HYDROGEN PEROXIDE

(71) Applicant: Gelest, Inc., Morrisville, PA (US)

(72) Inventors: Chad Michael BRICK, Yardley, PA (US); Tomoyuki OGATA, Tokyo (JP)

(21) Appl. No.: 19/174,221

(22) Filed: Apr. 9, 2025

Related U.S. Application Data
(60) Provisional application No. 63/634,538, filed on Apr. 16, 2024.

(51) Int. Cl. C23C 16/455; C23C 16/24; C23C 16/56

(52) U.S. Cl. CPC C23C 16/4554; C23C 16/24; C23C 16/45534; C23C 16/45553; C23C 16/56

(57) ABSTRACT

Provided are methods for increasing the deposition rate and improving the film properties of silicon-containing films via plasma-enhanced atomic layer deposition (PEALD) by utilization of hydrogen peroxide. In particular, an exposure to hydrogen peroxide before, during, or after the plasma exposure step of a low temperature PEALD process utilizing silicon-containing compounds results in increased deposition rates and superior film characteristics as compared to PEALD processes using plasma alone. Additionally, the disclosed process may utilize non-oxidizing plasmas, increasing the range of substrates to which the process can be applied relative to those compatible with oxidizing plasmas.

### CROSS-REFERENCE TO RELATED APPLICATIONS

This application claims priority to U.S. provisional application No. 63/634,538, filed Apr. 16, 2024, the disclosure of which is herein incorporated by reference in its entirety.

### BACKGROUND OF THE INVENTION

Silicon dioxide (SiO₂) deposited via plasma-enhanced atomic layer deposition (PEALD) is widely used in the semiconductor field. In particular, PEALD silicon dioxide is used in lithographic processes such as double pattering or quadruple patterning. In these processes, a conformal layer of silicon dioxide is deposited either directly onto a patterned photoresist or photoresist-defined patterned underlayers, denoted as “mandrels,” and then etched in such a manner that the thick vertical regions of SiO₂ deposited on the mandrel sidewalls are retained and both the thin horizontally deposited SiO₂ on flat surfaces and the mandrel are removed, resulting in two lithographic features instead of the previous single mandrel. This process may then be repeated to form four, eight, or more features in what are termed quadruple patterning, octuple patterning, and so forth.

A critical element of the SiO₂ deposition step of the sequence is that the deposition temperature must be low enough to protect the delicate mandrels from degradation, while minimizing the well-known tendency of the etch resistance of silicon dioxide deposited by atomic layer deposition (ALD) or chemical vapor deposition (CVD) processes to decrease with decreasing deposition temperature, while additionally maintaining a sufficiently high growth rate. To meet these targets, PEALD using silicon compounds such as bis(diethylamino)silane (BDEAS) and di(isopropylamino)silane (DIPAS) can be used along with an oxygen-based plasma to form conformal SiO₂ films at temperatures of around 50° C. to 200° C. What is desired is the ability to deposit these films at even lower temperatures and less oxidizing conditions in order to further protect the mandrels and their pattern integrity, while simultaneously increasing the deposition rate and increasing the etch resistance of the final SiO₂ patterns. Such rapid, low-temperature deposition of high-quality SiO₂ films is also desirable in other application areas, such as encapsulation of organic materials or devices upon polymer substrates, and may be used in applications such as biomedicine, photovoltaics, displays, or photonics.

Silicon dioxide films have a wide range of applications, for example, in the fabrication of integrated circuits, such as sacrificial layers, etch stop layers, passivation, encapsulation, low-k spacers, and antireflection layers. In many cases, such a lithographic multipatterning, plasma-enhanced atomic layer deposition is used to deposit silicon dioxide films at low temperatures such as about 200° C. or about 100° C. in order to protect the temperature-sensitive layers upon which the silicon dioxide films are being deposited. However, at temperatures below 100° C., the deposition rate of PEALD films with some silicon-based compounds begins to fall due to a complex interaction between physical absorption, chemical absorption, surface hydroxylation and impurities such as hydrogen, nitrogen and carbon, limiting the ability to extend this technique to even lower temperatures where a wider variety of substrates can be utilized and plasma damage can be reduced. Furthermore, low-temperature deposition of silicon dioxide films by PEALD utilizing non-oxidizing plasmas, which are less damaging to many substrates than oxidizing plasmas, is unreported.

In Liang et al., (Coatings, 12, 1411 (2022)), a process for depositing silicon dioxide films at a temperature of about 60° C. using plasma-enhanced chemical deposition (PECVD) is disclosed. While the reported electrical performance was suitable for some applications, step coverage was limited by the anisotropic nature of a chemical vapor deposition process.

In Dallorto et al., (Nanotechnology, 29, 405302 (2018)), synergistic effects between a silicon-based compound 3DMAS and oxygen plasma with respect to degradation of a carbon-based hardmask are discussed. The authors concluded that high temperature (300° C.) plasma deposition of silicon dioxide using 3DMAS and oxygen plasma was incompatible with carbon hardmasks.

In U.S. Pat. No. 12,057,320 B2 (RASIRC, Inc) hydrogen peroxide plasma was used to replace oxygen plasma for the etching of ashable hard masks. It is disclosed that relative to O₂-derived oxidizing plasmas, the reduction in the formation of oxygen radicals when using hydrogen peroxide as the plasma oxidant source reduces substrate damage. Furthermore, the increase in plasma hydroxyl radicals results in increased hydroxylation of the substrate.

There remains a need in the art for a method for the rapid deposition of silicon-containing films at low temperatures and under weakly oxidizing conditions that reduce the potential for substrate damage.

### SUMMARY OF THE INVENTION

One embodiment of the disclosure relates to a method for depositing a silicon-containing layer on a substrate, the method comprising:
(a) introducing a substrate into a reaction zone of a deposition chamber;
(b) alternately exposing the substrate to at least one silicon-containing compound and to a reactive process, wherein the reactive process comprises sequentially exposing the substrate to a non-oxidizing plasma and to hydrogen peroxide; and
(c) repeating step (b) until a desired layer thickness is obtained.

A second embodiment of the disclosure relates to a method for depositing a silicon-containing layer on a substrate, the method comprising:
(f) introducing a substrate into a reaction zone of a deposition chamber;
(g) alternately exposing the substrate to at least one silicon-containing compound and to a reactive process, wherein the reactive process comprises sequentially exposing the substrate to an oxidizing plasma and to hydrogen peroxide; and
(h) repeating step (g) until a desired layer thickness is obtained.

Advantageous refinements of the invention, which can be implemented alone or in combination, are specified in the dependent claims.

In summary, the following embodiments are proposed as particularly preferred in the scope of the present invention:

Embodiment 1: A method for depositing a silicon-containing layer on a substrate, the method comprising:
(a) introducing a substrate into a reaction zone of a deposition chamber;
(b) alternately exposing the substrate to at least one silicon-containing compound and to a reactive process, wherein the reactive process comprises sequentially exposing the substrate to a non-oxidizing plasma and to hydrogen peroxide; and
(c) repeating step (b) until a desired layer thickness is obtained.

Embodiment 2: The method according to Embodiment 1, wherein the hydrogen peroxide exposure in step (b) precedes the plasma exposure.

Embodiment 3: The method according to Embodiment 1, wherein the plasma exposure in step (b) precedes the hydrogen peroxide exposure.

Embodiment 4: The method according to any of Embodiments 1 to 3, wherein the at least one silicon-containing compound comprises at least one silicon-nitrogen bond, silicon-halide bond, or silicon-oxygen bond.

Embodiment 5: The method according to any of Embodiments 1 to 4, wherein the at least one silicon-containing compound has Formula 1, Formula 2, Formula 3, Formula 4, Formula 5, Formula 6, Formula 7, or Formula 8, wherein R₁, R₂, R₃, R₄, R₅, and R₆ are independently hydrogen, halide, isocyanato, linear or branched (C₁-C₁₂)alkyl, linear or branched (C₁-C₈)alkoxy, or N(R₁₂)(R₁₃); R₇, R₈, R₉, R₁₀, R₁₂, R₁₃, and R₁₉ are hydrogen, linear or branched (C₁-C₆)alkyl, or Si(R₁₄)(R₁₅)(R₁₆); R₁₄, R₁₅, and R₁₆ are hydrogen, halide, (C₁-C₁₂)alkyl, linear or branched (C₁-C₈)alkoxy, or N(R₁₇)(R₁₈); X is O, N(R₁₉), or linear or branched (C₁-C₈)alkyl; R₁₇ and R₁₈ are hydrogen or linear or branched (C₁-C₆)alkyl; R₁₁ is hydrogen or linear or branched (C₁-C₈)alkyl; m, and n are 1, 2 or 3; U, V and W are optionally bidentate and may be O, N(R₁₂), or linear or branched (C₁-C₄)alkyl; and Y and Z are optionally bidentate and are linear or branched (C₁-C₄)alkyl; and wherein the at least one silicon-containing compound contains at least one silicon-nitrogen, silicon-halide, or silicon-oxygen-carbon bond.

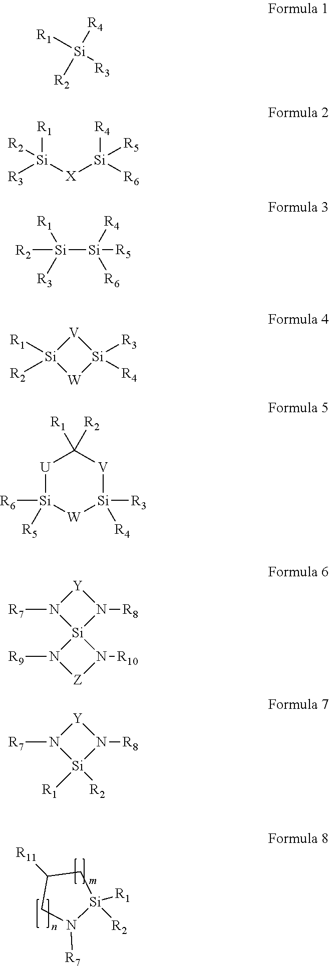

Embodiment 6: The method according to any of Embodiments 1 to 5, wherein the at least one silicon-containing compound is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3,2-diazasilolidine, trimethoxy(dimethylamino)silane, tris(dimethylamino)methylsilane, tetraethoxysilane, tetramethoxysilane, tetrachlorosilane, tetraisocyanatosilane, n-methyl-aza-2,2,4-trimethylsilacyclopentane, 2,2,5,5-tetramethyl-1,2,5-azadisilolidine, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, N-trimethylsilyl-aza-4-methylsilacyclopentane, 1,3-bis(dimethylamino)-1,3-disilacyclobutane, bis(t-butylamino)silane, bid(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, and hexa(dimethylamino)disilazane.

Embodiment 7: The method according to Embodiment 6, wherein the at least one silicon-containing compound is tris(dimethylamino)silane, bis(diethylamino)silane, trimethoxy(dimethylamino)silane, or di(isopropylamino)silane.

Embodiment 8: The method according to any of Embodiments 1 to 7, wherein a temperature of the reaction zone is below about 200° C.

Embodiment 9: The method according to Embodiment 8, wherein the temperature of the reaction zone is below about 100° C.

Embodiment 10: The method according to Embodiment 9, wherein the temperature of the reaction zone is below about 50° C.

Embodiment 11: The method according to any of Embodiments 1 to 10, wherein the non-oxidizing plasma comprises nitrogen, ammonia, hydrazine, argon, hydrogen, or a combination thereof.

Embodiment 12: The method according to any of Embodiments 1 to 11, further comprising prior to step (a):
(a1) performing at least one ex-situ annealing, cleaning, etching, polishing, oxidation, reduction, photolysis, UV/ozone exposure, chemical modification, or plasma treatment of the substrate.

Embodiment 13: The method according to any of Embodiments 1 to 12, further comprising after step (a) and prior to step (b):
(b1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Embodiment 14: The method according to any of Embodiments 1 to 13, wherein after step (c), the method further comprises:
(d) heating or cooling the reaction zone to about 0° C. to about 800° C.; and
(e) performing at least one in-situ or ex-situ passivation, annealing, cleaning, etching, polishing, oxidation, reduction, photolysis, UV/ozone exposure, or plasma treatment of the substrate.

Embodiment 15: The method according to Embodiment 14, further comprising after step (e);
(k) Repeating steps (a) through (e) until a desired layer thickness is reached.

Embodiment 16: A method for depositing a silicon-containing layer on a substrate, the method comprising:
(f) introducing a substrate into a reaction zone of a deposition chamber;
(g) alternately exposing the substrate to at least one silicon-containing compound and to a reactive process, wherein the reactive process comprises sequentially exposing the substrate to an oxidizing plasma and to hydrogen peroxide; and
(h) repeating step (g) until a desired layer thickness is obtained.

Embodiment 17: The method according to Embodiment 16, wherein the hydrogen peroxide exposure in step (g) precedes the plasma exposure.

Embodiment 18: The method according to Embodiment 16, wherein the plasma exposure in step (g) precedes the hydrogen peroxide exposure.

Embodiment 19: The method according to any of Embodiments 16 to 18, wherein the oxidizing plasma comprises a hydrogen peroxide plasma, and wherein the method further comprises providing an additional exposure of the substrate to hydrogen peroxide before or after the exposure to hydrogen peroxide plasma.

Embodiment 20: The method according to any of Embodiments 16 to 19, wherein the at least one silicon-containing compound comprises at least one silicon-nitrogen bond, silicon-halide bond, or silicon-oxygen bond.

Embodiment 21: The method according to any of Embodiments 16 to 20, wherein the at least one silicon-containing compound has Formula 1, Formula 2, Formula 3, Formula 4, Formula 5, Formula 6, Formula 7, or Formula 8, wherein R₁, R₂, R₃, R₄, R₅, and R₆ are independently hydrogen, halide, isocyanato, linear or branched (C₁-C₁₂)alkyl, linear or branched (C₁-C₈)alkoxy, or N(R₁₂)(R₁₃); R₇, R₈, R₉, R₁₀, R₁₂, R₁₃, and R₁₉ are hydrogen, linear or branched (C₁-C₆)alkyl, or Si(R₁₄)(R₁₅)(R₁₆); R₁₄, R₁₅, and R₁₆ are hydrogen, halide, (C₁-C₁₂)alkyl, linear or branched (C₁-C₈)alkoxy, or N(R₁₇)(R₁₈); X is O, N(R₁₉), or linear or branched (C₁-C₈)alkyl; R₁₇ and R₁₈ are hydrogen or linear or branched (C₁-C₆)alkyl; Ru is hydrogen or linear or branched (C₁-C₈)alkyl; m, and n are 1, 2 or 3; U, V and W are optionally bidentate and may be O, N(R₁₂), or linear or branched (C₁-C₄)alkyl; and Y and Z are optionally bidentate and are linear or branched (C₁-C₄)alkyl; and wherein the at least one silicon-containing compound contains at least one silicon-nitrogen, silicon-halide, or silicon-oxygen-carbon bond.

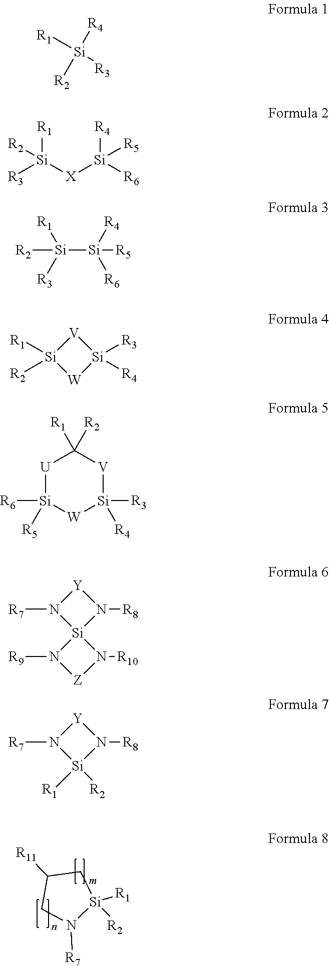

Embodiment 22: The method according to any of Embodiments 16 to 21, wherein the at least one silicon-containing compound is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3,2-diazasilolidine, trimethoxy(dimethylamino)silane, tris(dimethylamino)methylsilane, tetraethoxysilane, tetramethoxysilane, tetrachlorosilane, tetraisocyanatosilane, n-methyl-aza-2,2,4-trimethylsilacyclopentane, 2,2,5,5-tetramethyl-1,2,5-azadisilolidine, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, N-trimethylsilyl-aza-4-methylsilacyclopentane, 1,3-bis(dimethylamino)-1,3-disilacyclobutane, bis(t-butylamino)silane, bid(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, and hexa(dimethylamino)disilazane.

Embodiment 23: The method according to Embodiment 22, wherein the at least one silicon-containing compound is tris(dimethylamino)silane, bis(diethylamino)silane, trimethoxy(dimethylamino)silane, or di(isopropylamino)silane.

Embodiment 24: The method according to any of Embodiments 16 to 23, wherein a temperature of the reaction zone is below about 200° C.

Embodiment 25: The method according to Embodiment 24, wherein the temperature of the reaction zone is below about 100° C.

Embodiment 26: The method according to Embodiment 25, wherein the temperature of the reaction zone is below about 50° C.

Embodiment 27: The method according to any of Embodiments 16 to 26, wherein the oxidizing plasma comprises oxygen plasma, water plasma, hydrogen peroxide plasma, nitrous oxide plasma, carbon dioxide plasma, or a combination thereof.

Embodiment 28: The method according to any of Embodiments 16 to 27, further comprising prior to step (f):
(f1) performing at least one ex-situ annealing, cleaning, etching, polishing, oxidation, reduction, photolysis, UV/ozone exposure, chemical modification, or plasma treatment of the substrate.

Embodiment 29: The method according to any of Embodiments 16 to 28, further comprising after step (f) and prior to step (g):
(g1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Embodiment 30: The method according to any of Embodiments 16 to 29, wherein after step (h), the method further comprises:
(i) heating or cooling the reaction zone to about 0° C. to about 800° C.; and
(i) performing at least one in-situ or ex-situ passivation, annealing, cleaning, etching, polishing, oxidation, reduction, photolysis, UV/ozone exposure, or plasma treatment of the substrate.

Embodiment 31: The method according to Embodiment 30, further comprising after step (j);
(l) Repeating steps (f) through (j) until a desired layer thickness is reached.

### BRIEF DESCRIPTION OF THE SEVERAL VIEWS OF THE DRAWINGS

The foregoing summary, as well as the following detailed description of the invention, will be better understood when read in conjunction with the appended drawing. For the purpose of illustrating the invention, there is shown in the drawing embodiments which are presently preferred. It should be understood, however, that the invention is not limited to the precise arrangements and instrumentalities shown. In the drawings:

FIG. 1 is a graph of comparing growth rates of BDEAS under various conditions.

### DETAILED DESCRIPTION OF THE INVENTION

Aspects of the disclosure relate to methods of adding an exposure to hydrogen peroxide to a traditional two-step PEALD sequence for the creation of silicon-containing films. Such a standard two-step method of PEALD comprises alternating an exposure of a silicon-containing chemical compound with an exposure to plasma. This may be done by alternately moving the silicon-containing compound and plasma into a reaction zone of a deposition chamber containing the substrate (temporal PEALD) or moving the substrate between two different reaction zones, one containing the silicon-containing compound and one containing plasma (spatial PEALD). In the case of temporal PEALD, exposures to the silicon-containing compound and plasma are typically separated by a purge of the reaction zone with an inert gas or vacuum to avoid gas-phase reactions of the silicon-containing compound and plasma. Likewise, in spatial PEALD, the respective silicon-containing compound and plasma reaction zones are typically separated by areas of inert gas purging or vacuum in order to avoid gas-phase reactions of the silicon-containing compound and the plasma.

In general terms, the disclosure is directed to two distinct methods for depositing a silicon-containing layer on a substrate by employing a silicon-containing compound, a plasma (oxidizing or non-oxidizing), and hydrogen peroxide. In one method, the method involves sequential exposures of the substrate to a non-oxidizing plasma and to hydrogen peroxide. In the second method, the method involves sequential exposures of the substrate to an oxidizing plasma and to hydrogen peroxide

A method of forming a silicon-containing layer on a substrate according to the first aspect of this disclosure comprises:
(a) introducing a substrate into a reaction zone of a deposition chamber;
(b) alternately exposing the substrate to at least one silicon-containing compound and to a reactive process, wherein the reactive process comprises sequentially exposing the substrate to a non-oxidizing plasma and to hydrogen peroxide; and
(c) repeating step (b) until a desired layer thickness is obtained.
   These steps will be described in further detail below.

In some embodiments, the method further comprises, prior to step (a):
(a1) performing at least one ex-situ annealing, cleaning, etching, polishing, oxidation, reduction, photolysis, UV/ozone exposure, chemical modification, or plasma treatment of the substrate.

In some embodiments, the method further comprises, after step (a) and prior to step (b):
(b1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Steps (a1) and (b1) are optional processes that may be undertaken to prepare the substrate for the atomic layer deposition processes of step (b). Steps (a1) and (b1) may include one or more processes known in the art such annealing, cleaning, etching, polishing, oxidation, reduction, photolysis, UV/ozone exposure, or plasma treatment of the substrate. These processes may be independently performed before placing the substrate in the atomic layer deposition tool or reactor, termed ex-situ (step (a1)) or inside the atomic layer deposition reactor, termed in-situ (step (b1)). The temperature of any preparatory step (a1) or (b1) may be selected independently of each other or of that of the atomic layer deposition process that is defined in step (b), and is not limited to the temperature ranges disclosed in step (b).

In some embodiments the method may further involve the following additional steps after step (c):
(d) heating or cooling the same or a different reaction zone to about 0° C. to about 800° C.; and
(e) performing at least one in-situ or ex-situ passivation, annealing, cleaning, etching, polishing, oxidation, reduction, photolysis, UV/ozone exposure, passivation, or plasma treatment of the substrate. In such cases, the method may further comprise (k) repeating steps (a) or (a1) though (e) until a desired layer thickness is reached.

Steps (d) and (e) may occur after the deposition process defined in steps (a), (b) and (c) is complete in order to modify the properties of one or more components of the film or the substrate, or to prepare the substrate for subsequent processes. Alternatively, steps (d) and (e) may occur in the middle of the overall deposition process as part of a “super-cycle,” in which the cycle of steps (a), (b), (c), (d), (e) and optionally steps (a1) or (b1) is repeated more than one time until a desired layer or film thickness is reached. By periodic addition of the optional steps (d) and (e) to the overall deposition process, the properties of one more components of the film or substrate may be modified. Step (e) may include ex-situ processes performed in a different tool than that of the disclosed silicon-containing film deposition process, or in-situ processes performed in the same tool as the silicon-containing film deposition process. These processes may be done at ambient temperatures, sub-ambient temperatures such as about 10° C. or about 0° C., or at elevated temperatures such as about 100° C., about 200° C., about 400° C. or about 800° C., as suitable for the particular process. Likewise, step (e) may be carried out under ambient atmosphere, oxidizing or reducing atmospheres, vacuum, or under inert gas as is appropriate for the specific process. The process conditions of step (e) such as temperature, pressure, and atmospheric composition of the post-treatment processes may be selected independently of those of the silicon-containing deposition process. In the case that step (e) is an in-situ process that occurs in the same reaction zone of a deposition chamber as step (c), step (d) is unnecessary.

Step (b) comprises a plasma-enhanced atomic layer deposition (PEALD) process comprising:
i) Exposing the substrate to at least one silicon-containing compound;
ii) Exposing the substrate to a gas stream containing hydrogen peroxide; and
iii) Exposing the substrate to a non-oxidizing plasma.

Steps (b)-ii and (b)-iii may be performed in either order but may not overlap. That is, the exposures of the substrate to hydrogen peroxide and to non-oxidizing plasma are performed sequentially. In some embodiments, the hydrogen peroxide exposure precedes the plasma exposure, whereas in other embodiments, the plasma exposure precedes the hydrogen peroxide exposure.

Appropriate silicon-containing compounds are described in detail below. The exposure of the substrate to at least one silicon-containing compound in step (b)-i may be for about 0.01 seconds to about 60 seconds, preferably about 0.1 to about 30 seconds, more preferably about 0.5 to about 10 seconds. The exposures of the substrate to hydrogen peroxide in step (b)-ii and to the non-oxidizing plasma in step (b)-iii may be performed in either order but may not overlap, i.e., the exposures to hydrogen peroxide and non-oxidizing plasma are sequential and not simultaneous. The exposure in steps (b)-ii and (b)-iii may be for about 1 second to about 60 seconds, preferably about 2 seconds to about 40 seconds, or most preferably about 5 seconds to about 20 seconds.

In step (b), a non-oxidizing plasma is used. While not limiting, the plasma may a non-oxidizing plasma comprising a nitrogen plasma, ammonia plasma, hydrogen plasma, hydrazine plasma, or argon plasma, or a combination of more than one such plasma.

In the case of temporal PEALD, steps (b)-i, (b)-ii and (b)-iii may be optionally separated by purges of the reaction zone with one or more inert gases such as nitrogen, helium, neon, or argon, or by evacuation of the reaction zone by vacuum, or a combination thereof. These purging and evacuation steps may be about 0.5 second to about 20 seconds, preferably about 1 second to about 15 seconds, or more preferably about 2 seconds to about 10 seconds.

In the case of spatial PEALD, the reaction zones of steps (b)-i, (b)-ii, and (b)-iii are physically separated from one another and may be further physically separated from one another by zones of vacuum or inert gas purging.

In the case of non-oxidizing plasmas and a silicon-containing compound that lacks oxygen atoms, minimal silicon dioxide film growth occurs with plasma alone due to the lack of an oxygen source other than adventitious oxygen. In the case of non-oxidizing plasmas and a silicon-containing compound that comprises oxygen atoms, such as TMDMAS, slow growth of silicon dioxide may occur. However, by adding an exposure to hydrogen peroxide before or after the exposure to the non-oxidizing plasma, film growth similar to or even greater than that obtained with oxygen plasma may be achieved. The use of a non-oxidizing plasma may be highly advantageous when all or part of the substrate is comprised of materials that are sensitive to strongly oxidizing conditions, including organic materials, such as spin-on-carbon films or polymer encapsulation films, or metals, such as, but not limited to, copper, cobalt, molybdenum, or ruthenium.

A method of forming a silicon-containing layer on a substrate according to a second aspect of this disclosure comprises:
(f) introducing a substrate into a reaction zone of a deposition chamber;
(g) alternately exposing the substrate to at least one silicon-containing compound and to a reactive process, wherein the reactive process comprises sequentially exposing the substrate to an oxidizing plasma and to hydrogen peroxide; and
(h) repeating step (g) until a desired layer thickness is obtained.
   These steps will be described in further detail below.

In some embodiments, the method further comprises, prior to step (f):
(f1) performing at least one ex-situ annealing, cleaning, etching, polishing, oxidation, reduction, photolysis, UV/ozone exposure, chemical modification, or plasma treatment of the substrate.

In some embodiments, the method further comprises, after step (f) and prior to step (g):
(g1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Steps (f1) and (g1) are optional processes that may be undertaken to prepare the substrate for the atomic layer deposition processes of step (g). Steps (f1) and (g1) may include one or more processes known in the art such annealing, cleaning, etching, polishing, oxidation, reduction, photolysis, UV/ozone exposure, or plasma treatment of the substrate. These processes may be independently performed before placing the substrate in the atomic layer deposition tool, termed ex-situ (step (f1)) or inside the atomic layer deposition reactor, termed in-situ (step (g1)). The temperature of any preparatory step (f1) or (g1) may be selected independently of each other or of that of the atomic layer deposition process that is defined in step (g), and is not limited to the temperature ranges disclosed in step (g).

In some embodiments the method may further involve the following additional steps after step (h):
(i) optionally heating or cooling the same or different reaction zone to about 0° C. to about 800° C.; and
(j) performing at least one in-situ or ex-situ passivation, annealing, cleaning, etching, polishing oxidation, reduction, photolysis, UV/ozone exposure, passivation, or plasma treatment of the substrate. In such cases, the method may further comprise (1) repeating steps (f) or (f1) though (j) until a desired layer thickness is reached.

Steps (i) and (j) may occur after the deposition process defined in steps (f), (g) and (h) is complete in order to modify the properties of one or more components of the film or the substrate, or to prepare the substrate for subsequent processes. Alternatively, steps (i) and (j) may occur in the middle of the overall deposition process as part of a “super-cycle”, in which the cycle of steps (f), (g), (h), (i), (j) and optionally steps (f1) or (g1) are repeated more than one time until a desired film thickness is reached. By periodic addition of the optional steps (i) and (j) to the overall deposition process, the properties of one more components of the film or substrate may be modified. Step (j) may include ex-situ processes performed in a different tool than that of the disclosed silicon-containing film deposition process, or in-situ processes performed in the same tool as the silicon-containing film deposition process. These processes may be done at ambient temperatures, sub-ambient temperatures such as about 10° C. or about 0° C., or at elevated temperatures such as about 100° C., about 200° C., about 400° C. or about 800° C., as suitable for the particular process. Likewise, step (j) may be carried out under ambient atmosphere, oxidizing or reducing atmospheres, vacuum, or under inert gas as is appropriate for the specific process. The process conditions of step j) such as temperature, pressure, and atmospheric composition of the post-treatment processes may be selected independently of those of the silicon-containing deposition process. In the case that step j) is an in-situ process that occurs in the same reaction zone of a deposition chamber as step (j), step (i) is unnecessary.

Step (g) comprises a plasma-enhanced atomic layer deposition (PEALD) process comprising:
iv) Exposing the substrate to at least one silicon-containing compound;
v) Exposing the substrate to a gas stream containing hydrogen peroxide; and
vi) Exposing the substrate to an oxidizing plasma.

Steps (g)-v and (g)-vi may be performed in either order. That is, exposures of the substrate to hydrogen peroxide and to oxidizing plasma are performed sequentially. In some embodiments, the hydrogen peroxide exposure precedes the plasma exposure, whereas in other embodiments, the plasma exposure precedes the hydrogen peroxide exposure. In some embodiments, the oxidizing plasma comprises hydrogen peroxide. In this case, the exposure of the substrate to a gas stream containing hydrogen peroxide in step (g)-v must be separate from the exposure to the oxidizing plasma in step (g)-vi, which can be achieved by a variety of means. While not limiting, examples of methods of implementing separate exposures to a hydrogen peroxide gas stream and hydrogen peroxide plasma include two separate exposures to hydrogen peroxide, one of which involves plasma ignition (step (g)-vi) and one that does not (step (g)-v), one continuous exposure to hydrogen peroxide, during which plasma ignition only occurs during part of the hydrogen peroxide exposure (step (g)-vi) and not during a remainder (step (g)-v), or by physically separated regions of hydrogen peroxide exposure (step (g)-v) and hydrogen peroxide plasma exposure (step (g)-vi).

While not limiting, the exposure of the substrate to at least one silicon-containing compound in step (g)-iv may be for about 0.01 seconds to about 60 seconds, preferably about 0.1 to about 30 seconds, more preferably about 0.5 to about 10 seconds. The exposures of the substrate to hydrogen peroxide in step (g)-v and to plasma in step (g)-vi may be performed sequentially in either order The exposure of the substrate to hydrogen peroxide in step (g)-v may be for about 1 second to about 60 seconds, preferably about 2 seconds to about 40 seconds, or most preferably about 5 seconds to about 20 seconds. The exposure of the substrate to the oxidizing plasma in step (g)-vi may be for about 1 second to about 60 seconds, preferably about 2 seconds to about 40 seconds, or most preferably about 5 seconds to about 20 seconds.

In step (g), an oxidizing plasma is used. While not limiting, the plasma may an oxidizing plasma such as oxygen plasma, water plasma, hydrogen peroxide plasma, nitrous oxide plasma, or carbon dioxide plasma, or a combination of more than one such plasma. In one embodiment, the oxidizing plasma comprises a hydrogen peroxide plasma, and the method further comprises providing an additional exposure of the substrate to hydrogen peroxide before or after the exposure to hydrogen peroxide plasma.

In the case of temporal PEALD, steps (v)-iv, (g)-v and (g)-vi may be optionally separated by purges of the reaction zone with inert gases such as nitrogen, helium, neon, or argon, or by evacuation of the reaction zone by vacuum, or a combination thereof. These purging and evacuation steps may be for about 0.5 seconds to about 20 seconds, preferably about 1 second to about 15 seconds, or more preferably about 2 seconds to about 10 seconds.

In the case of spatial PEALD, the reaction zones of steps (g)-iv (g)-v, and (g)-vi are physically separated from one another and may be further physically separated from one another by zones of vacuum or inert gas purging.

In certain embodiments, an oxidizing plasma, such as a plasma comprising oxygen, hydrogen peroxide, water, nitrous oxide, or carbon dioxide, may be used. In the case of oxidizing plasma, the addition of an exposure to hydrogen peroxide before or after the plasma step of the PEALD sequence shows significant improvement in deposition rate relative to PEALD using oxygen plasma alone, as is shown in Table 1, which includes data from the Examples described below.

### First and Second Methods

Unless otherwise stated, any numerical value is to be understood as being modified in all instances by the term “about.” Thus, a numerical value typically includes ±10% of the recited value. For example, the recitation of a temperature such as “10° C.” or “about 10° C.” includes 9° C. and 11° C. and all temperatures therebetween.

All numerical ranges expressed in this disclosure expressly encompass all possible subranges, all individual numerical values within that range, including integers within such ranges and fractions and decimal amounts of the values unless the context clearly indicates otherwise. For example, a temperature range of 0° C. to about 200° C. includes temperatures of 0° C., 5° C., 10° C., 15° C., 20° C., 25° C., 30° C., 35° C., 40° C., 45° C., 50° C., 55° C., 60° C., 65° C., 70° C., 75° C., 80° C., 85° C., 90° C., 95° C., 100° C., 105° C., 110° C., 115° C., 120° C., 125° C., 130° C., 135° C., 140° C., 145° C., 150° C., 155° C., 160° C., 165° C., 170° C., 175° C., 180° C., 185° C., 190° C., 195° C. and 200° C. as well as all intervening temperatures.

In certain embodiments, the film deposited by the inventive process is a silicon dioxide film. As used herein, “silicon dioxide” refers to a film with an atomic composition, excluding hydrogen, of at least about 25% silicon and about 60% oxygen and at most about 2% carbon and about 2% nitrogen.

The term “thin film” is well understood in the art and may include films ranging in thickness from a few angstroms to a few microns. More specifically, the term “thin film” may be understood to refer to a film having a thickness of less than about 1,000 nm and preferably between about 0.3 nm and about 100 nm and more preferably between about 1 nm and about 30 nm, even more preferably between about 3 nm and about 20 nm. For the purposes of this disclosure, the terms “layer,” “film,” and “thin film” are synonymous.

In certain embodiments, hydrogen peroxide is used as a co-reactant along with a plasma for the formation of silicon-containing films. Hydrogen peroxide may be delivered by a variety of means, including vapor draw, bubbling, or direct liquid injection. While not limiting, the hydrogen peroxide source may be a water/hydrogen peroxide liquid mixture, such as 30 wt % or 50 wt % solutions of hydrogen peroxide in water, or water/hydrogen peroxide mixtures absorbed onto solids, such as BRUTE hydrogen peroxide (RASIRC Inc, San Diego, California) which comprises high purity (>95%) hydrogen peroxide absorbed onto a proprietary solid material enclosed in a custom delivery vessel. When the hydrogen peroxide is in mixture with water, the mixture preferably contains at least about 1 wt % hydrogen peroxide, preferably at least about 5 wt % hydrogen peroxide.

Embodiments of this disclosure relate to the use of hydrogen peroxide to increase the film deposition rates of silicon-containing films. The step of adding an exposure to hydrogen peroxide to the plasma-enhanced atomic layer deposition sequence results in the growth rate of films deposited by PEALD using compounds such as BDEAS, tris(dimethylamino)silane (3DMAS), and trimethoxy(dimethylamino)silane (TMDMAS) being significantly enhanced at low temperatures. As shown in Table 1, film deposition at rates of 0.121 nm/cycle can be achieved at deposition temperatures of 30° C., representing a significant improvement over films deposited under identical conditions without hydrogen peroxide exposure.

In steps (b) and (g), any silicon-containing chemical compound capable of chemically bonding to a hydroxylated substrate surface is within the scope of the disclosure. While not limiting, suitable silicon-containing chemical compounds comprise at least one silicon-nitrogen bond, silicon-halide bond, or silicon-oxygen bond. Such compounds include aminosilanes, cyclic azasilanes, halogenated silanes such as fluorosilanes, chlorosilanes, bromosilanes, or iodosilanes, isocyanato silanes and alkoxysilanes. Suitable compounds may have one silicon atom or more than one silicon atom, such as disilanes, 1,3-bis(silyl)methanes, 1,3-bis(silyl)ethanes, disiloxanes, disilazanes, or 4 to 12-member single or bis ring structures comprising silicon, nitrogen, oxygen, or carbon within the ring or rings.

More specifically, silicon-containing compounds having Formula 1, Formula 2, Formula 3, Formula 4, Formula 5, Formula 6, Formula 7, or Formula 8 are particularly suitable for the methods described herein.

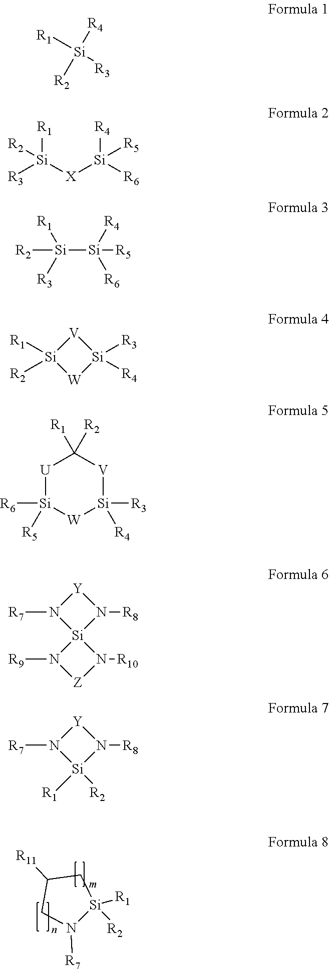

In Formulas 1-8, R₁, R₂, R₃, R₄, R₅, and R₆ are independently hydrogen, halide, isocyanate, linear or branched (C₁-C₁₂)alkyl, linear or branched (C₁-C₈)alkoxy, or N(R₁₂)(R₁₃); R₇, R₈, R₉, R₁₀, R₁₂, R₁₃, and R₁₉ are hydrogen, linear or branched (C₁-C₆)alkyl, or Si(R₁₄)(R₁₅)(R₁₆); R₁₄, R₁₅, and R₁₆ are hydrogen, halide, (C₁-C₁₂)alkyl, linear or branched (C₁-C₈)alkoxy, or N(R₁₇)(R₁₈); X is O, N(R₁₉), or linear or branched (C₁-C₈)alkyl; R₁₇ and R₁₈ are hydrogen or linear or branched (C₁-C₆)alkyl; R₁₁ is hydrogen or linear or branched (C₁-C₈)alkyl; m, and n are 1, 2 or 3; U, V and W are optionally bidentate and may be O, N(R₁₂), or linear or branched (C₁-C₄)alkyl; and Y and Z are optionally bidentate and are linear or branched (C₁-C₄)alkyl; and wherein the at least one silicon-containing compound contains at least one silicon-nitrogen, silicon-halide, or silicon-oxygen-carbon bond.

While not limiting, specific examples of suitable compounds include tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3,2-diazasilolidine, trimethoxy(dimethylamino)silane, tris(dimethylamino)methylsilane, tetraethoxysilane, tetramethoxysilane, tetrachlorosilane, tetraisocyanatosilane, n-methyl-aza-2,2,4-trimethylsilacyclopentane, 2,2,5,5-tetramethyl-1,2,5-azadisilolidine, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, N-trimethylsilyl-aza-4-methylsilacyclopentane, 1,3-bis(dimethylamino)-1,3-disilacyclobutane, bis(t-butylamino)silane, bid(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, and hexa(dimethylamino)disilazane, shown below.

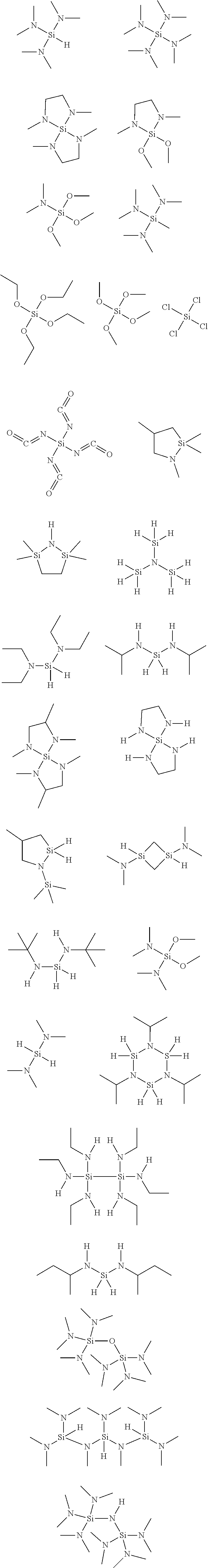

As used herein, the terms “substrate” or “substrate surface” refer to the base material upon which modifications or additions are made. Examples of substrate surfaces include semiconductors, such as silicon, germanium, or gallium arsenide, metals, such as copper, cobalt, ruthenium, molybdenum, tungsten, or their alloys, oxides, such as silicon dioxide, silicon oxycarbide, titanium dioxide, hafnium dioxide, alumina, or nitrides, such as silicon nitride, silicon carbon nitride, aluminum nitride, titanium nitride, or tantalum nitride. Substrate surfaces may be treated or altered in various ways, including pretreatment processes such as annealing, polishing, etching, hydroxylation, oxidation, reduction, passivation, modification with chemical compounds or plasma treatment. Additionally, new layers or films of other materials may be deposited onto the substrate surface. Importantly, the term “substrate surface” is flexible and may refer to the original substrate or the surface of any newly added layers. Furthermore, the substrate surface may be substantially planar or contain complex three-dimensional structures such as vias, pillars, trenches, or pores. The specific materials and processes used will determine the composition and structure of the final substrate surface.

While not limiting, the term substrate may comprise a semiconductor wafer, chip, panel or device, a display panel, or a solar wafer or panel, or a polymer film. As used herein, a semiconductor device is an electronic component that relies on the electronic properties of a semiconductor material for its function.

In certain embodiments, the process used to deposit the inventive films may be described as a plasma-enhanced “atomic layer deposition,” “plasma-enhanced ALD,” or “PEALD” process. While not limiting, a plasma-enhanced atomic layer deposition process involves alternate exposures of a substrate to one or more chemical compounds which react with the substrate surface and to a plasma which reacts with the one or more compounds to form a film, separated by optional purges of the reaction zone with inert gas in order to prevent vapor-phase interaction of the chemical compounds and the plasma. The alternating exposures of compounds and a second chemical compound may be achieved by alternatively moving the compounds and plasma in and out of a reaction zone containing the substrate (temporal ALD) or alternatively moving the substrate into different reaction zones, at least one of which contains one or more chemical compounds and at least one of which contains plasma (spatial ALD). The period of time that the substrate is exposed to a compound or plasma is referred to as a “pulse,” and typically ranges from milliseconds to tens of seconds, as is defined herein for specific steps of the process.

In certain embodiments, the temperature of the reaction zone is about 200° C. or less, or more preferably about 100° C. or less, and most preferably about 50° C. or less.

According to aspects of the disclosure, the deposition rate for the deposition steps is greater than about 0.3 angstroms per cycle and the cycle time is less than about 120 seconds. According to further aspects of the disclosure, the deposition rate is greater than about 0.5 angstroms per cycle and the cycle time less than about 60 seconds.

A variety of pre-deposition processes may be applied to the substrate in order to remove contamination, planarize, or chemically modify the surface, or modify the chemical, mechanical, or electric properties of one or more regions of the substrate. While not limiting, these may include annealing, cleaning, wet or dry etching, polishing, oxidation, reduction, photolysis, UV/ozone exposure, chemical modification, passivation or plasma treatment of the substrate and may include ex-situ processes performed in a different tool than that of the disclosed silicon-containing film deposition process, or in-situ processes performed in the same tool as the silicon-containing film deposition process. These pre-deposition processes may be done at ambient temperatures, sub-ambient temperatures such as about 10° C. or about 0° C., or at elevated temperatures such as about 100° C., about 200° C., about 400° C., or about 800° C., as suitable for the particular process. Likewise, the pre-deposition processes may be carried out under ambient atmosphere, oxidizing or reducing atmospheres, vacuum, or under inert gas as is appropriate for the specific process. The processes conditions such as temperature, pressure, and atmospheric composition of the pre-treatment processes may be selected independently of those of the silicon-containing deposition process.

Correspondingly, the same set of processes may occur after deposition is complete in order to modify the properties of one or more components of the film or the substrate, or to prepare the substrate for subsequent processes. These post-deposition processes may include ex-situ processes performed in a different tool or reactor than that of the disclosed silicon-containing film deposition process, or in-situ processes performed in the same tool as the silicon-containing film deposition process. These post-deposition processes may be done at ambient temperatures, sub-ambient temperatures such as about 10° C. or about 0° C., or at elevated temperatures such as about 100° C., about 200° C., about 400° C. or about 800° C., as suitable for the particular process. Likewise, the post-deposition processes may be carried out under ambient atmosphere, oxidizing or reducing atmospheres, vacuum, or under inert gas as is appropriate for the specific process. The processes conditions such as temperature, pressure, and atmospheric composition of the post-treatment processes may be selected independently of those of the silicon-containing deposition process.

Thermal annealing comprises heating the substrate under inert (nitrogen, noble gas, carbon dioxide), oxidizing (oxygen, air, ozone, hydrogen peroxide, nitrous oxide), or reducing (hydrogen, ammonia, hydrocarbon) atmospheres, at pressures ranging from about 0.01 torr to about 1000 torr and temperatures of about 20° C. to about 800° C. for about one second to about twelve hours. Thermal annealing may be supplemented by electromagnetic radiation. Such photoannealing processes utilize various forms of light, such as microwaves, infrared, visible light, ultraviolet light, x-rays or gamma rays, which may be tuned as appropriate for the excitement of chemical bonds within one or more layers of the substrate. Likewise, thermal annealing may also be supplemented with electron beams, whose energy and power are tuned as appropriate for the excitement of chemical bonds within one or more layers of the substrate.

Annealing may occur under vacuum, under inert atmospheres such as nitrogen or argon, or under reactive atmospheres. While not limiting, reactive atmospheres may include oxidizing environments comprising air, oxygen, water, hydrogen peroxide, or ozone, reducing environments such as hydrogen, hydrocarbons, amines, or ammonia, or atmospheres including molecules such as aminosilanes, alkoxysilanes, or chlorosilanes which will react with the substrate surface.

The invention will now be described in connection with the following, non-limited examples.

### Example 1: Low Temperature Deposition of Silicon Dioxide Using BDEAS, BRUTE Hydrogen Peroxide and Oxygen Plasma

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to bis(diethylamino)silane (5 seconds), hydrogen peroxide (20 seconds) delivered by a RASIRC BRUTE hydrogen peroxide delivery system, and oxygen plasma (10 seconds), separated by 10 second purges with nitrogen gas were performed. Film growth of 1.21 angstroms per cycle was observed by in-situ ellipsometry. A film composition of silicon dioxide with less than 1% carbon and 1% nitrogen was confirmed by x-ray photoelectron spectroscopy (XPS).

### Example 2: Low Temperature Deposition of Silicon Dioxide Using BDEAS, BRUTE Hydrogen Peroxide and Nitrogen Plasma

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to bis(diethylamino)silane (5 seconds), hydrogen peroxide (20 seconds) delivered by a RASIRC BRUTE hydrogen peroxide delivery system, and nitrogen plasma (10 seconds), separated by 10 second purges with nitrogen gas were performed. Film growth of 1.02 angstroms per cycle was observed by in-situ ellipsometry. A film composition of silicon dioxide with less than 1% carbon and 1% nitrogen was confirmed by x-ray photoelectron spectroscopy (XPS).

### Example 3 (Comparative): Low Temperature Deposition of Silicon Dioxide Using BDEAS and Oxygen Plasma

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to bis(diethylamino)silane (5 seconds) and oxygen plasma (10 seconds), separated by 15 second purges with nitrogen gas were performed. Film growth of 0.71 angstroms per cycle was observed by in-situ ellipsometry. A film composition of silicon dioxide with less than 1% carbon and 1% nitrogen was confirmed by x-ray photoelectron spectroscopy (XPS).

### Example 4: Low Temperature Deposition of Silicon Dioxide Using TMDMAS, BRUTE Hydrogen Peroxide and Oxygen Plasma

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to trimethoxy(dimethylamino)silane (5 seconds), hydrogen peroxide (20 seconds) delivered by a RASIRC BRUTE hydrogen peroxide delivery system, and oxygen plasma (10 seconds), separated by 10 second purges with nitrogen gas were performed. Film growth of 0.53 angstroms per cycle was observed by in-situ ellipsometry.

### Example 5: Low Temperature Deposition of Silicon Dioxide Using TMDMAS, BRUTE Hydrogen Peroxide and Nitrogen Plasma

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to trimethoxy(dimethylamino)silane (5 seconds), hydrogen peroxide (20 seconds) delivered by a RASIRC BRUTE hydrogen peroxide delivery system, and nitrogen plasma (10 seconds), separated by 10 second purges with nitrogen gas were performed. Film growth of 0.54 angstroms per cycle was observed by in-situ ellipsometry.

### Example 6: Low Temperature Deposition of Silicon Dioxide Using TMDMAS, Oxygen Plasma, and BRUTE Hydrogen Peroxide

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to trimethoxy(dimethylamino)silane (5 seconds), oxygen plasma (10 seconds), and hydrogen peroxide (20 seconds) delivered by a RASIRC BRUTE hydrogen peroxide delivery system, separated by 10 second purges with nitrogen gas were performed. Film growth of 0.57 angstroms per cycle was observed by in-situ ellipsometry.

### Example 7: Low Temperature Deposition of Silicon Dioxide Using TMDMAS, Nitrogen Plasma, and Hydrogen Peroxide

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to trimethoxy(dimethylamino)silane (5 seconds), nitrogen plasma (10 seconds), and hydrogen peroxide (20 seconds) delivered by a RASIRC BRUTE hydrogen peroxide delivery system, separated by 10 second purges with nitrogen gas were performed. Film growth of 0.47 angstroms per cycle was observed by in-situ ellipsometry. A film composition of silicon dioxide with less than 1% carbon and 1% nitrogen was confirmed by x-ray photoelectron spectroscopy (XPS).

### Example 8 (Comparative): Low Temperature Deposition of Silicon Dioxide Using TMDMAS and Oxygen Plasma

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to trimethoxy(dimethylamino)silane (5 seconds) and oxygen plasma (10 seconds), separated by 15 second purges with nitrogen gas were performed. Film growth of 0.53 angstroms per cycle was observed by in-situ ellipsometry.

### Example 9 (Comparative): Low Temperature Deposition of Silicon Dioxide Using TMDMAS and Nitrogen Plasma

A silicon coupon with 1000 nm of thermally-grown silicon dioxide was placed in a reaction chamber at 30° C. The coupon was exposed to one minute of oxygen plasma in order to remove adventitious contamination, and then 25 ALD cycles of sequential exposures to trimethoxy(dimethylamino)silane (5 seconds) and nitrogen plasma (10 seconds), separated by 15 second purges with nitrogen gas were performed. Film growth of 0.18 angstroms per cycle was observed by in-situ ellipsometry.

### Examples 10-21

Twelve additional experiments were carried out as described in Example 4, using different compounds and temperatures. The data are tabulated in Table 1.

### Examples 22-33

Twelve additional experiments were carried out as described in Example 5, using different compounds and temperatures. The data are tabulated in Table 1.

### Examples 34-35

Two additional experiments were carried out as described in Example 6, using different compounds and temperatures. The data are tabulated in Table 1.

### Examples 36-37

Two additional experiments were carried out as described in Example 7, using different compounds and temperatures. The data are tabulated in Table 1.

### Examples 38-49: (Comparative)

Twelve additional comparative experiments were carried out as described in Example 8 (comparative), using different compounds and temperatures. The data are tabulated in Table 1.

### Example 50 (Comparative)

An additional comparative experiment was carried out as described in Example 9 (comparative), at 100° C. The data are tabulated in Table 1.

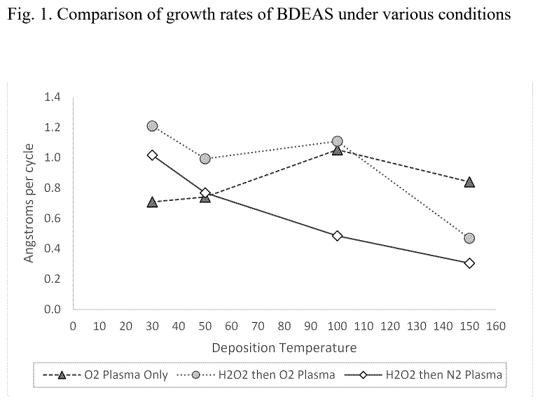

The data from the Examples above are tabulated in Table 1 below and the BDEAS data are depicted in FIG. 1.

TABLE 1
Growth rates per cycle for various silanes under
various conditions using RASIRC BRUTE Peroxide.

| | | Silicon Dioxide Growth Rate - Angstroms per Cycle | | | | | |
|---|---|---|---|---|---|---|---|
| Temp | | O₂ | H₂O₂ then | H₂O₂ then | O₂ Plasma | N₂ Plasma | |
| (deg C.) | Compound | Plasma | O₂ Plasma | N₂ Plasma | then H₂O₂ | then H₂O₂ | N₂ Plasma |
| 30 | BDEAS | 0.71 | 1.21 | 1.02 | | | Not |
| 50 | BDEAS | 0.74 | 0.99 | 0.77 | | | applicable |
| 100 | BDEAS | 1.05 | 1.11 | 0.48 | | | |
| 150 | BDEAS | 0.84 | 0.47 | 0.30 | | | |
| 30 | 3DMAS | 0.86 | 1.06 | 1.10 | 1.27 | 0.97 | Not |
| 50 | 3DMAS | 0.70 | 0.85 | 1.00 | | | applicable |
| 75 | 3DMAS | 0.74 | 0.75 | 0.56 | | | |
| 100 | 3DMAS | 0.82 | 0.79 | 0.57 | | | |
| 150 | 3DMAS | 0.71 | 0.80 | 0.38 | 0.78 | 0.25 | |
| 200 | 3DMAS | 0.64 | 0.74 | 0.25 | | | |
| 30 | TMDMAS | 0.53 | 0.53 | 0.54 | 0.57 | 0.47 | 0.18 |
| 50 | TMDMAS | 0.35 | 0.38 | 0.35 | | | |
| 100 | TMDMAS | 0.70 | 0.74 | 0.27 | | | 0.14 |
| 150 | TMDMAS | 0.80 | 0.70 | 0.23 | | | |

### Example 51: Low Temperature Deposition of Silicon Dioxide Using tris(dimethylamino)silane, 30% Hydrogen Peroxide in Water, and Oxygen Plasma

A silicon coupon with 1.7 nm of native dioxide was placed in a reaction chamber at 30° C. The coupon was exposed to ten seconds of oxygen plasma in order to remove adventitious contamination, and then 25 ALD cycles of sequential exposures to tris(dimethylamino)silane (5 seconds), hydrogen peroxide (20 seconds) delivered by vapor draw from a solution of 30% hydrogen peroxide in water, and oxygen plasma (10 seconds), separated by 10 second purges with nitrogen gas were performed. Film growth of 1.07 angstroms per cycle was observed by in-situ ellipsometry.

### Example 52: Low Temperature Deposition of Silicon Dioxide Using tris(dimethylamino)silane, Oxygen Plasma, and 30% Hydrogen Peroxide in Water

A silicon coupon with 1.7 nm of native dioxide was placed in a reaction chamber at 30° C. The coupon was exposed to ten seconds of oxygen plasma in order to remove adventitious contamination, and then 25 ALD cycles of sequential exposures to tris(dimethylamino)silane (5 seconds), oxygen plasma (10 seconds), hydrogen peroxide (20 seconds) delivered by vapor draw from a solution of 30% hydrogen peroxide in water, separated by 10 second purges with nitrogen gas were performed. Film growth of 1.41 angstroms per cycle was observed by in-situ ellipsometry.

The data from Examples 51 and 52 are tabulated in Table 2.

TABLE 2
Growth rates per cycle for 3DMAS and various
hydrogen peroxide sources.

| Growth Rate | Å/cycle | | |
|---|---|---|---|
| O₂ Plasma First | 1.413 | 1.270 | — |
| H₂O₂ First | 1.067 | 1.061 | — |
| O₂ Plasma Only | — | — | 0.862 |
| | 30% H₂O₂ | RASIRC BRUTE | Plasma |
| | in Water | Peroxide (>95%) | only |

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method for depositing a silicon-containing layer on a substrate, the method comprising:
(a) introducing a substrate into a reaction zone of a deposition chamber;
(b) alternately exposing the substrate to at least one silicon-containing compound and to a reactive process, wherein the reactive process comprises sequentially exposing the substrate to a non-oxidizing plasma and to hydrogen peroxide; and
(c) repeating step (b) until a desired layer thickness is obtained.

2. The method according to claim 1, wherein the hydrogen peroxide exposure in step (b) precedes the plasma exposure.

3. The method according to claim 1, wherein the plasma exposure in step (b) precedes the hydrogen peroxide exposure.

4. The method according to claim 1, wherein the at least one silicon-containing compound comprises at least one silicon-nitrogen bond, silicon-halide bond, or silicon-oxygen bond.

5. The method according to claim 1, wherein the at least one silicon-containing compound has Formula 1, Formula 2, Formula 3, Formula 4, Formula 5, Formula 6, Formula 7, or Formula 8, wherein R₁, R₂, R₃, R₄, R₅, and R₆ are independently hydrogen, halide, isocyanato, linear or branched (C₁-C₁₂)alkyl, linear or branched (C₁-C₈)alkoxy, or N(R₁₂)(R₁₃); R₇, R₈, R₉, R₁₀, R₁₂, R₁₃, and R₁₉ are hydrogen, linear or branched (C₁-C₆)alkyl, or Si(R₁₄)(R₁₅)(R₁₆); R₁₄, R₁₅, and R₁₆ are hydrogen, halide, (C₁-C₁₂)alkyl, linear or branched (C₁-C₈)alkoxy, or N(R₁₇)(R₁₈); X is O, N(R₁₉), or linear or branched (C₁-C₈)alkyl; R₁₇ and R₁₈ are hydrogen or linear or branched (C₁-C₆)alkyl; R₁₁ is hydrogen or linear or branched (C₁-C₈)alkyl; m, and n are 1, 2 or 3; U, V and W are optionally bidentate and may be O, N(R₁₂), or linear or branched (C₁-C₄)alkyl; and Y and Z are optionally bidentate and are linear or branched (C₁-C₄)alkyl; and wherein the at least one silicon-containing compound contains at least one silicon-nitrogen, silicon-halide, or silicon-oxygen-carbon bond.

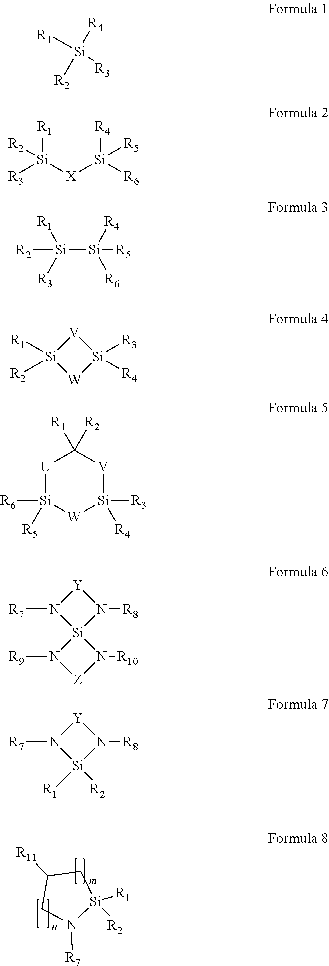

6. The method according to claim 1, wherein the at least one silicon-containing compound is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3,2-diazasilolidine, trimethoxy(dimethylamino)silane, tris(dimethylamino)methylsilane, tetraethoxysilane, tetramethoxysilane, tetrachlorosilane, tetraisocyanatosilane, n-methyl-aza-2,2,4-trimethylsilacyclopentane, 2,2,5,5-tetramethyl-1,2,5-azadisilolidine, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, N-trimethylsilyl-aza-4-methylsilacyclopentane, 1,3-bis(dimethylamino)-1,3-disilacyclobutane, bis(t-butylamino)silane, bid(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, and hexa(dimethylamino)disilazane.

7. The method according to claim 6, wherein the at least one silicon-containing compound is tris(dimethylamino)silane, bis(diethylamino)silane, trimethoxy(dimethylamino)silane, or di(isopropylamino)silane.

8. The method according to claim 1, wherein a temperature of the reaction zone is below about 200° C.

9. The method according to claim 8, wherein the temperature of the reaction zone is below about 100° C.

10. The method according to claim 9, wherein the temperature of the reaction zone is below about 50° C.

11. The method according to claim 1, wherein the non-oxidizing plasma comprises nitrogen, ammonia, hydrazine, argon, hydrogen, or a combination thereof.

12. The method according to claim 1, further comprising prior to step (a):
(a1) performing at least one ex-situ annealing, cleaning, etching, polishing, oxidation, reduction, photolysis, UV/ozone exposure, chemical modification, or plasma treatment of the substrate.

13. The method according to claim 1, further comprising after step (a) and prior to step (b):
(b1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

14. The method according to claim 1, wherein after step (c), the method further comprises:
(d) optionally heating or cooling the reaction zone to about 0° C. to about 800° C.; and
(e) performing at least one in-situ or ex-situ passivation, annealing, cleaning, etching, polishing, oxidation, reduction, photolysis, UV/ozone exposure, or plasma treatment of the substrate.

15. The method according to claim 14, further comprising after step (e);
(k) Repeating steps (a) through (e) until a desired layer thickness is reached.

16. A method for depositing a silicon-containing layer on a substrate, the method comprising:
(f) introducing a substrate into a reaction zone of a deposition chamber;
(g) alternately exposing the substrate to at least one silicon-containing compound and to a reactive process, wherein the reactive process comprises sequentially exposing the substrate to an oxidizing plasma and to hydrogen peroxide; and
(h) repeating step (g) until a desired layer thickness is obtained.

17. The method according to claim 16, wherein the hydrogen peroxide exposure in step (g) precedes the plasma exposure.

18. The method according to claim 16, wherein the plasma exposure in step (g) precedes the hydrogen peroxide exposure.

19. The method according to claim 16, wherein the oxidizing plasma comprises a hydrogen peroxide plasma, and wherein the method further comprises providing an additional exposure of the substrate to hydrogen peroxide before or after the exposure to hydrogen peroxide plasma.

20. The method according to claim 16, wherein the at least one silicon-containing compound comprises at least one silicon-nitrogen bond, silicon-halide bond, or silicon-oxygen bond.

21. The method according to claim 16, wherein the at least one silicon-containing compound has Formula 1, Formula 2, Formula 3, Formula 4, Formula 5, Formula 6, Formula 7, or Formula 8, wherein R₁, R₂, R₃, R₄, R₅, and R₆ are independently hydrogen, halide, isocyanato, linear or branched (C₁-C₁₂)alkyl, linear or branched (C₁-C₈)alkoxy, or N(R₁₂)(R₁₃); R₇, R₈, R₉, R₁₀, R₁₂, R₁₃, and R₁₉ are hydrogen, linear or branched (C₁-C₆)alkyl, or Si(R₁₄)(R₁₅)(R₁₆); R₁₄, R₁₅, and R₁₆ are hydrogen, halide, (C₁-C₁₂)alkyl, linear or branched (C₁-C₈)alkoxy, or N(R₁₇)(R₁₈); X is O, N(R₁₉), or linear or branched (C₁-C₈)alkyl; R₁₇ and R₁₈ are hydrogen or linear or branched (C₁-C₆)alkyl; R₁₁ is hydrogen or linear or branched (C₁-C₈)alkyl; m, and n are 1, 2 or 3; U, V and W are optionally bidentate and may be O, N(R₁₂), or linear or branched (C₁-C₄)alkyl; and Y and Z are optionally bidentate and are linear or branched (C₁-C₄)alkyl; and wherein the at least one silicon-containing compound contains at least one silicon-nitrogen, silicon-halide, or silicon-oxygen-carbon bond.

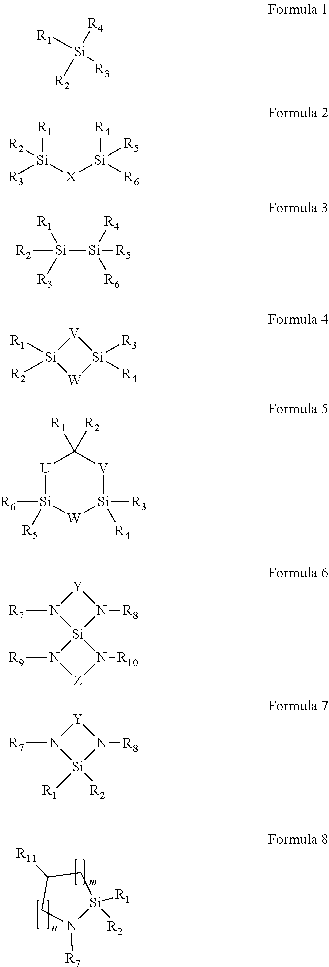

22. The method according to claim 16, wherein the at least one silicon-containing compound is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3,2-diazasilolidine, trimethoxy(dimethylamino)silane, tris(dimethylamino)methylsilane, tetraethoxysilane, tetramethoxysilane, tetrachlorosilane, tetraisocyanatosilane, n-methyl-aza-2,2,4-trimethylsilacyclopentane, 2,2,5,5-tetramethyl-1,2,5-azadisilolidine, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, N-trimethylsilyl-aza-4-methylsilacyclopentane, 1,3-bis(dimethylamino)-1,3-disilacyclobutane, bis(t-butylamino)silane, bid(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, and hexa(dimethylamino)disilazane.

23. The method according to claim 22, wherein the at least one silicon-containing compound is tris(dimethylamino)silane, bis(diethylamino)silane, trimethoxy(dimethylamino)silane, or di(isopropylamino)silane.

24. The method according to claim 16, wherein a temperature of the reaction zone is below about 200° C.

25. The method according to claim 24, wherein the temperature of the reaction zone is below about 100° C.

26. The method according to claim 25, wherein the temperature of the reaction zone is below about 50° C.

27. The method according to claim 16, wherein the oxidizing plasma comprises oxygen plasma, water plasma, hydrogen peroxide plasma, nitrous oxide plasma, carbon dioxide plasma, or a combination thereof.

28. The method according to claim 16, further comprising prior to step (f):
(f1) performing at least one ex-situ annealing, cleaning, etching, polishing, oxidation, reduction, photolysis, UV/ozone exposure, chemical modification, or plasma treatment of the substrate.

29. The method according to claim 16, further comprising after step (f) and prior to step (g):
(g1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

30. The method according to claim 16, wherein after step (h), the method further comprises:
(i) optionally heating or cooling the reaction zone to about 0° C. to about 800° C.; and
(i) performing at least one in-situ or ex-situ passivation, annealing, cleaning, etching, polishing, oxidation, reduction, photolysis, UV/ozone exposure, or plasma treatment of the substrate.

31. The method according to claim 30, further comprising after step (j);
(l) Repeating steps (f) through (j) until a desired layer thickness is reached.
